(19) United States
(12) Patent Application Publication
(10) Pub. No.: US 2024/0147825 A1
(43) Pub. Date: May 2, 2024

(54) PIXEL DEFINING ENCAPSULATING BARRIER FOR RGB COLOR PATTERNING

(71) Applicant: Applied Materials, Inc., Santa Clara, CA (US)

(72) Inventors: Chung-chia CHEN, San Jose, CA (US); Yu-Hsin LIN, Zhubei City (TW); Ji Young CHOUNG, Hwaseong-si (KR); Jungmin LEE, Santa Clara, CA (US); Wen-Hao WU, San Jose, CA (US); Dieter HAAS, San Jose, CA (US)

(21) Appl. No.: 17/974,385

(22) Filed: Oct. 26, 2022

(51) Int. Cl. H01L 51/56; H01L 27/32; H01L 51/52

(52) U.S. Cl. CPC H01L 51/56; H01L 27/3246; H01L 51/5253; H01L 2227/323; H01L 2251/5315

(57) ABSTRACT

Examples disclosed herein relate to device. The device includes a substrate, a plurality of adjacent pixel-defining layer (PDL structures disposed over the substrate, and a plurality of sub-pixels. The PDL structure have a top surface coupled to adjacent sidewalls of the PDL structure. The plurality of sub-pixels are defined by the PDL structures. Each sub-pixel includes an anode, an organic light emitting diode (OLED), a cathode, and an encapsulation layer. The organic light emitting diode (OLED) material disposed over the anode. The OLED material extends over the top surface of the PDL structure past the adjacent sidewalls. The cathode is disposed over the OLED material. The cathode extends over the top surface of the PDL structure past the adjacent sidewalls. The encapsulation layer is disposed over the cathode. The encapsulation layer has a first sidewall and a second sidewall.

### BACKGROUND

### Field

Embodiments of the present disclosure generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photolithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits that may be utilized in a display such as an organic OLED display.

### SUMMARY

In one embodiment, a device is provided. The device includes a substrate, a plurality of adjacent pixel-defining layer (PDL) structures disposed over the substrate, and a plurality of sub-pixels defined by the PDL structures. The PDL structure has a top surface coupled to adjacent sidewalls of the PDL structure. Each sub-pixel includes an anode, an organic light emitting diode (OLED) material, a cathode, and an encapsulation layer. The organic light emitting diode (OLED) material is disposed over the anode. The OLED material has a first OLED end and a second OLED end that extend over the top surface of the PDL structure past the adjacent sidewalls. The cathode is disposed over the OLED material. The cathode has a first cathode end and a second cathode end that extend over the top surface of the PDL structure past the adjacent sidewalls. An encapsulation layer is disposed over the cathode. The encapsulation layer has a first sidewall and a second sidewall, wherein the first sidewall and the second sidewall extend past the first OLED end, the second OLED end, the first cathode end, and the second cathode end.

In another embodiment, a method of forming a device is provided. The method includes positioning a substrate. The substrate includes a first opening of a first sub-pixel defined by a plurality of adjacent pixel-defining layer (PDL) structures disposed over the substrate and a first anode defined by the adjacent PDL structures. The method further includes depositing an OLED material, a cathode, and an encapsulation layer of the first sub-pixel over the substrate, forming a resist in a well of the first sub-pixel, removing the encapsulation layer of the first sub-pixel exposed by the resist of the first sub-pixel, removing the OLED material and the cathode of the first sub-pixel exposed by the resist of the first sub-pixel. The method further includes positioning the substrate, the substrate further including a second opening of a second sub-pixel defined by the plurality of PDL structures disposed over the substrate and a second anode defined by the adjacent PDL structures. The method then includes depositing an OLED material, a cathode, and an encapsulation layer of the second sub-pixel over the substrate, forming a resist in a well of the second sub-pixel, removing the encapsulation layer of the second sub-pixel exposed by the resist, removing the OLED material and cathode of the second sub-pixel exposed by the resist, and removing the resist of the second sub-pixel.

In another embodiment, a device is provided. The device includes a substrate, a plurality of adjacent pixel-defining layer (PDL) structures disposed over the substrate, and a plurality of sub-pixels defined by the PDL structures. The PDL structure has a top surface coupled to adjacent sidewalls of the PDL structure. Each sub-pixel includes an anode, an organic light emitting diode (OLED) material, a cathode disposed over the anode, a plug, an encapsulation layer disposed over the plug. The OLED material has a first OLED end and a second OLED end that extend over the top surface of the PDL structure past the adjacent sidewalls. The cathode has a first cathode end and a second cathode end that extend over the top surface of the PDL structure past the adjacent sidewalls. The plug is disposed over the cathode. The encapsulation layer is disposed over the plug. The encapsulation layer has a first sidewall and a second sidewall. The first sidewall and the second sidewall extend past the first OLED end, the second OLED end, the first cathode end, and the second cathode end.

In another embodiment, a method of forming a device is provided. The method includes positioning a substrate. The substrate includes a first opening of a first sub-pixel defined by a plurality of adjacent pixel-defining layer (PDL) structures disposed over the substrate and a first anode defined by the adjacent PDL structures. The method further includes depositing an OLED material, a cathode, and an encapsulation layer of the first sub-pixel over the substrate, forming a plug in a well of the first sub-pixel, the plug having a first plug transmittance that is matched or substantially matched to an OLED transmittance of the OLED material of the first sub-pixel, removing the encapsulation layer of the first sub-pixel exposed by the plug of the first sub-pixel, removing the OLED material and the cathode of the first sub-pixel exposed by the plug of the first sub-pixel, depositing a second encapsulation layer over the plug and first encapsulation layer of the first sub-pixel, and removing portions of the second encapsulation layer disposed over a second sub-pixel. The method further includes positioning the substrate. The substrate further includes a second opening of the second sub-pixel defined by the plurality of PDL structures disposed over the substrate and a second anode defined by the adjacent PDL structures. The method further includes depositing an OLED material, a cathode, and an encapsulation layer of the second sub-pixel over the substrate, forming a plug in a well of the second sub-pixel, the plug having a first plug transmittance that is matched or substantially matched to an OLED transmittance of the OLED material of the first sub-pixel, removing the first encapsulation layer of the second sub-pixel exposed by the plug of the second sub-pixel, removing the OLED material and cathode of the second sub-pixel exposed by the plug of the second sub-pixel, depositing a second encapsulation layer over the plug and first encapsulation layer of the second sub-pixel, and removing portions of the second encapsulation layer disposed over a first sub-pixel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit having a plugless arrangement, according to embodiments.

FIG. 1B is a schematic, cross-sectional view of a sub-pixel circuit having a plug arrangement, according to embodiments.

FIG. 1C is a schematic, top sectional view of a sub-pixel circuit having a dot-type architecture, according to embodiments.

FIG. 1D is a schematic, cross-sectional view of a sub-pixel circuit having a line-type architecture, according to embodiments.

FIG. 2 is a flow diagram of a method for forming a sub-pixel circuit, according to embodiments.

FIGS. 3A-3P are schematic, cross-sectional views of a substrate during a method for forming a sub-pixel circuit, according embodiments.

FIG. 4 is a flow diagram of a method for forming a sub-pixel circuit, according to embodiments.

FIGS. 5A-5P are schematic, cross-sectional views of a substrate during a method for forming a sub-pixel circuit, according embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

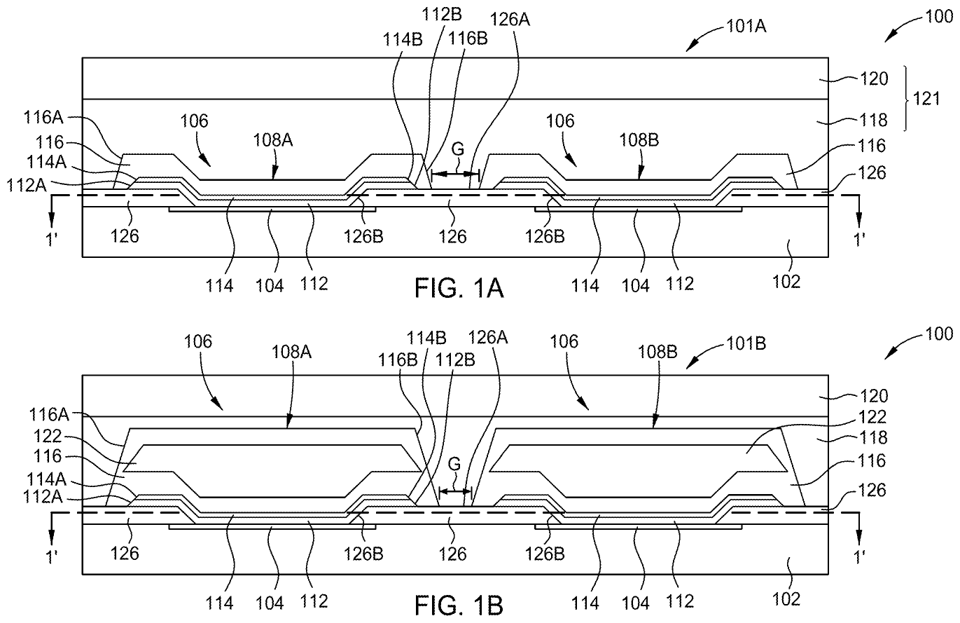

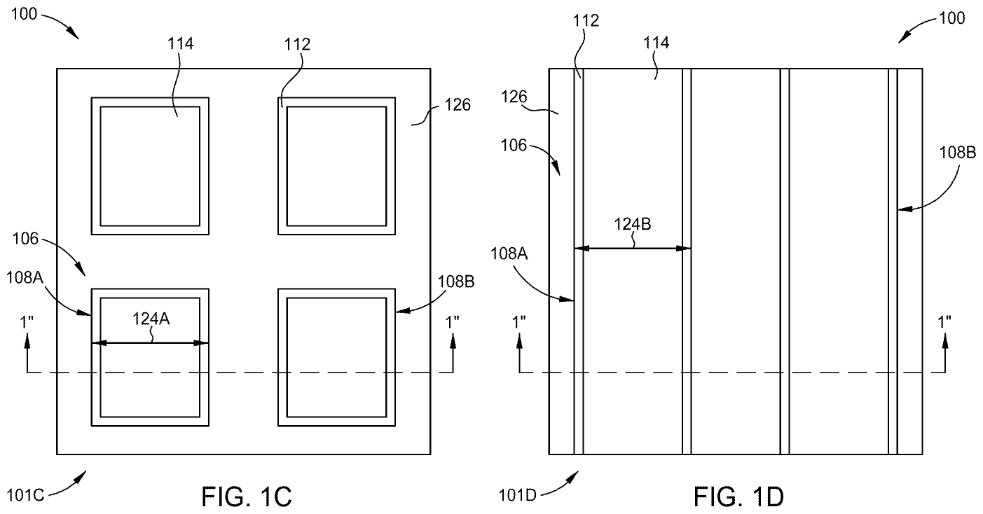

FIG. 1A is a schematic, cross-sectional view of a sub-pixel circuit 100 having a plugless arrangement 101A. The cross-sectional view of FIG. 1A is taken along section line 1″-1″ of FIGS. 1C and 1D. FIG. 1B is a schematic, cross-sectional view of a sub-pixel circuit 100 having a plug arrangement 101B. The cross-sectional view of FIG. 1B is taken along section line 1″-1″ of FIGS. 1C and 1D.

The sub-pixel circuit 100 includes a substrate 102. Metal-containing layers 104 may be patterned on the substrate 102 and are defined by adjacent pixel-defining layer (PDL) structures 126 disposed on the substrate 102. In one embodiment, the metal-containing layers 104 are pre-patterned on the substrate 102. E.g., the substrate 102 is a pre-patterned indium tin oxide (ITO) glass substrate. The metal-containing layers 104 are configured to operate as anodes of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal containing layer. The metal-containing layers 104 include, but are not limited to, chromium, titanium, gold, silver, copper, aluminum, ITO, a combination thereof, or other suitably conductive materials.

The PDL structures 126 are disposed on the substrate 102. The PDL structures include a top surface 126A coupled to two adjacent sidewalls 126B. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 126 define a respective sub-pixel and expose the anode (i.e., metal-containing layer 104) of the respective sub-pixel of the sub-pixel circuit 100.

The sub-pixel circuit 100 has a plurality of sub-pixels 106 including at least a first sub-pixel 108A and a second sub-pixel 108B. While the Figures depict the first sub-pixel 108A and the second sub-pixel 108B, the sub-pixel circuit 100 of the embodiments described herein may include three or more sub-pixels 106, such as a third and fourth sub-pixel. Each sub-pixel 106 has an organic light-emitting diode (OLED) material 112 configured to emit a white, red, green, blue or other color light when energized. E.g., the OLED material 112 of the first sub-pixel 108A emits a red light when energized, the OLED material of the second sub-pixel 108B emits a green light when energized, the OLED material of a third sub-pixel emits a blue light when energized, and the OLED material of a fourth sub-pixel and a fifth sub-pixel emits another color light when energized. In one embodiment, the OLED material is different than the material of the PDL structures 126. The OLED material 112 is disposed over the PDL structures 126. In one embodiment, the OLED material 112 is disposed on the top surface 126A of the PDL structures 126. In one embodiment, the OLED material has a first end 112A and a second end 112B disposed over a top surface 126A of the adjacent PDL structures 126 and extending past an endpoint of the metal-containing layer 104. In another embodiment, the first end 112A of the OLED material 112 extends past a respective sidewall 126B of the PDL structures 126 and the second end 112B of the OLED material 112 extends past another respective sidewall 126B of the PDL structures 126.

A cathode 114 is disposed over the OLED material 112. In one embodiment, the cathode 114 is disposed on the OLED material 112. The cathode includes a conductive material, such as a metal or metal alloy. E.g., the cathode 114 includes, but is not limited to, chromium, titanium, aluminum, ITO, or a combination thereof. In one embodiment, the material of the cathode 114 is different from the material of the OLED material 112 and the PDL structures 126. In one embodiment, the cathode 114 contacts an assistant cathode (not shown). In another embodiment, the cathode 114 contacts busbars (not shown) outside of an active area of the sub-pixel circuit 100. The cathode further includes a first end 114A and a second end 114B. The first end 114A and the second end 114B are disposed over the top surface 126A of the adjacent PDL structures 126. In one embodiment, the first end 112A and second end 112B of the OLED material extends further over the top surface 126A of the adjacent PDL structures 126 than the first end 114A and second end 114B of the cathode. In one embodiment, the first end 114A and the second end 114B of the cathode 114 extend past the endpoint of the metal-containing layer 104. In another embodiment, the first end 114A of the cathode 114 extends past a respective sidewall 126B of the PDL structures 126 and the second end 114B of the cathode 114 extends past another respective sidewall 126B of the PDL structures 126.

Each sub-pixel 106 includes include an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116. The encapsulation layer 116 includes a first sidewall 116A and a second sidewall 116B. The first sidewall 116A and second sidewall 116B of the encapsulation layer 116 extend beyond the first end 112A and second end 112B of the OLED material 112. The first sidewall 116A and second sidewall 116B of the encapsulation layer 116 extend beyond the first end 114A and second end 114B of the cathode 114. The encapsulation layer 116 contacts the first end 112A, the second end 112B, the first end 114A, the second end 114B, and the top surface 126A. In one embodiment, a gap G separates the second sidewall 116B of the encapsulation layer 116 of the first pixel 108A from the first sidewall 116A of the encapsulation layer 116 of the second pixel 108B. The encapsulation layer 116 may be varied using deposition thicknesses. E.g., the encapsulation layer 116 may have a thickness 0.1 μm, and 2 μm. The encapsulation layer 116 includes a non-conductive inorganic material, such as a silicon-containing material. The silicon containing material may include Si₃N₄ containing materials. In one embodiment, the material of the encapsulation layer 116 is different from the material of the cathode 114, the OLED material 112 and the PDL structures 126.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. The plugless arrangement 101A and the plug arrangement 101B of the sub-pixel circuit 100 further includes a global passivation layer 121. The global passivation layer 121 is disposed over the encapsulation layer 116. In one embodiment, the global passivation layer 121 is disposed over the first sidewall 116A and second sidewall 116B of the encapsulation layer 116 and a portion of the top surface 126A of the PDL structures 126 in the gap G. In another embodiment, the global passivation layer 121 is disposed on the top surface 126A of the PDL structures 126 in the gap G. In yet another embodiment, the global passivation layer 121 may include an intermediate layer 118 and a passivation layer 120. In one embodiment, the intermediate layer 118 is disposed over the first sidewall 116A and second sidewall 126B of the PDL structures 126 and a portion of the top surface 126A of the PDL structures 126 in the gap G. In another embodiment, the intermediate layer 118 is disposed on the top surface 126A of the PDL structures 126 in the gap G. In another embodiment, the global passivation layer 121, the intermediate layer 118, and the passivation layer 120 do not contact the OLED material 112 or the cathode 114. The intermediate layer 118 may include an inkjet material, such as an acrylic material.

The plug arrangement 101B includes a plug 122 disposed within the encapsulation layers 116. Each plug 122 is disposed in a respective sub-pixel 106 of the sub-pixel circuit 100. The plugs 122 may have an additional passivation layer disposed thereon. The plugs include, but are not limited to, a photoresist, a color filter, or a photosensitive monomer. The plugs 122 have a plug transmittance that is matched or substantially matched to an OLED transmittance of the OLED material 112. The plugs 122 may each be the same material and match the OLED transmittance. The plugs 122 may be different materials that match the OLED transmittance of each respective sub-pixel of the plurality of sub-pixels 106. The matched or substantially matched plug transmittance and OLED transmittance allow for the plugs 122 to remain over the sub-pixels 106 over the sub-pixels 106 without blocking the emitted light from the OLED material 112. The plugs 122 are able to remain in place and thus do not require a lift off procedure to be removed from the sub-pixel circuit 100. Additional pattern resist materials disposed over the formed sub-pixels 106 at subsequent operations are not required because the plugs 122 remain. Eliminating the need for a lift-off procedure on the plugs and the need for additional pattern resist materials on the sub-pixel 100 increases throughout.

FIG. 1C is a schematic, top sectional view of a sub-pixel circuit 100 having a dot-type architecture 101C. FIG. 1D is a schematic, cross-sectional view of a sub-pixel circuit 100 having a line-type architecture 101D. Each of the top sectional views of FIGS. 1C and 1D are taken along section line 1′-1′ of FIGS. 1A and 1B. The dot-type architecture 101C includes a plurality of pixel openings 124A from adjacent PDL structures 126. Each of pixel openings 124A defines each of the sub-pixels 106 of the dot-type architecture 101C. The line-type architecture 101D includes a plurality of pixel openings 124B from adjacent PDL structures 126. Each of pixel openings 124B define each of the sub-pixels 106 of the line-type architecture 101D.

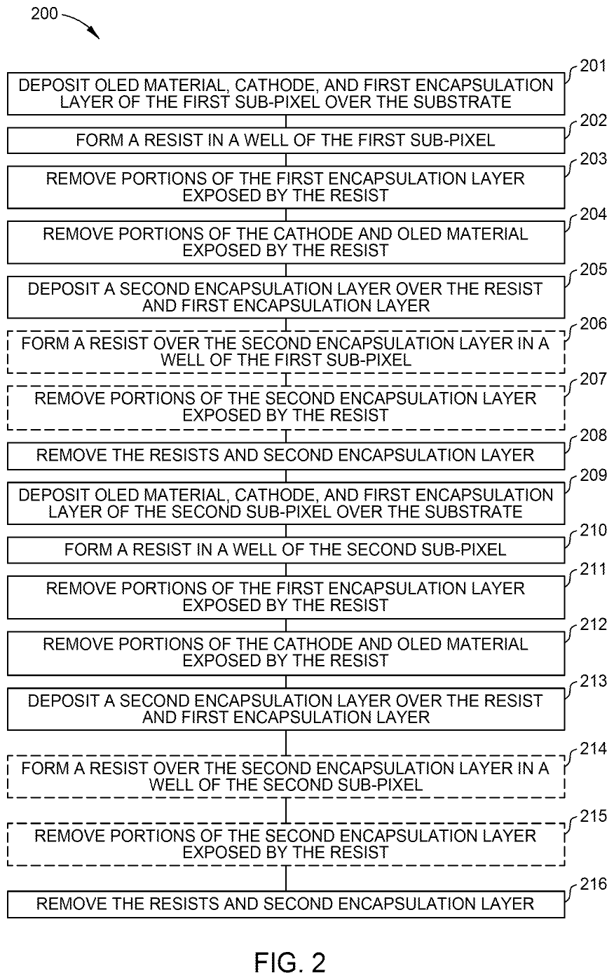

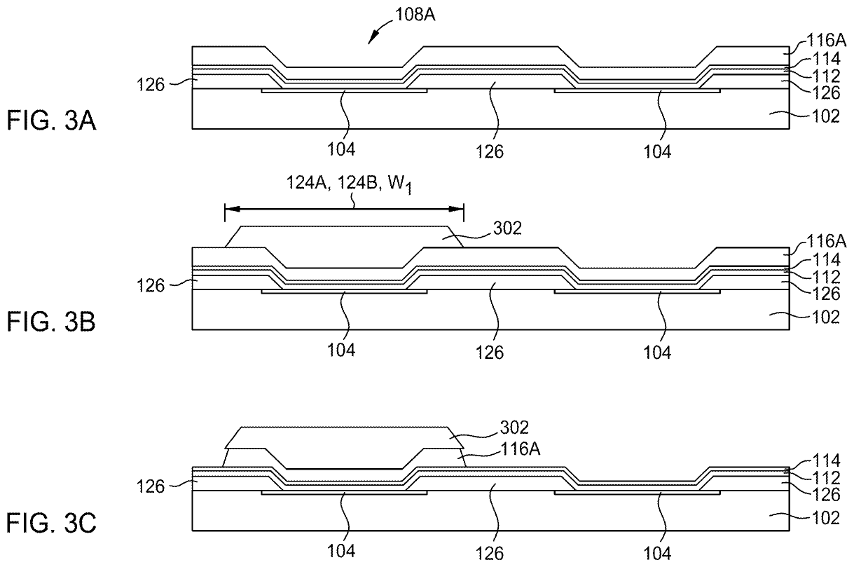

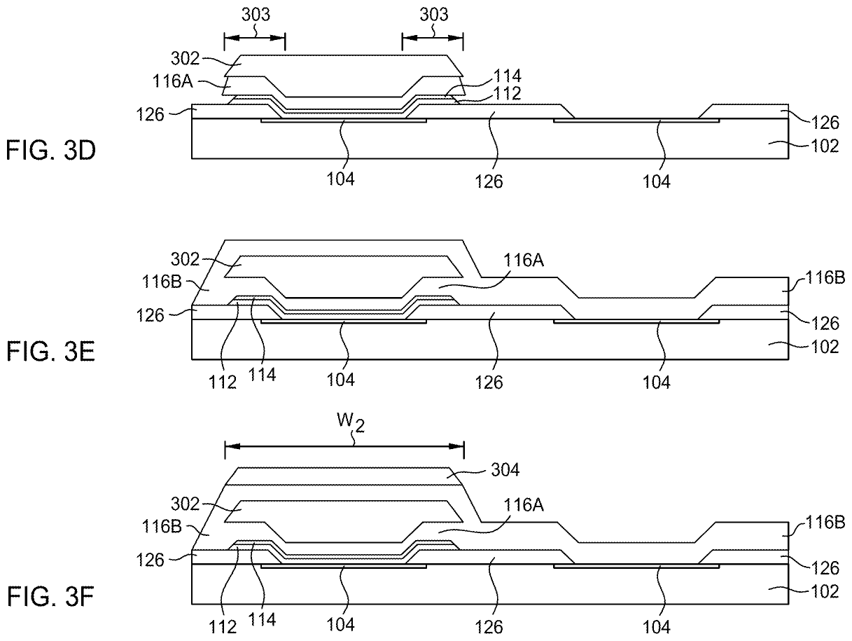

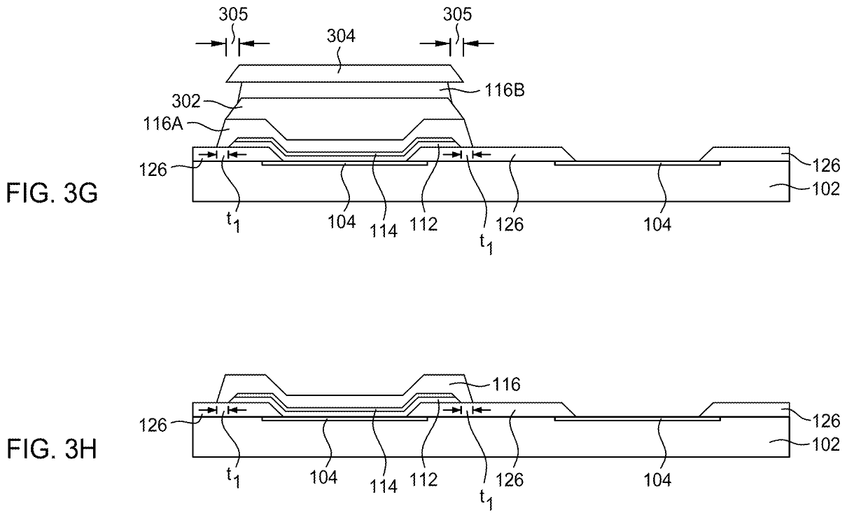

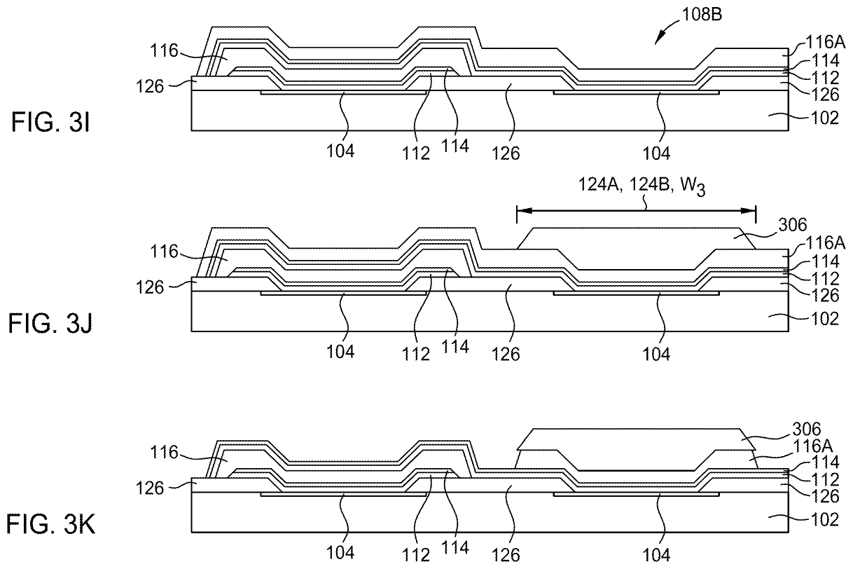

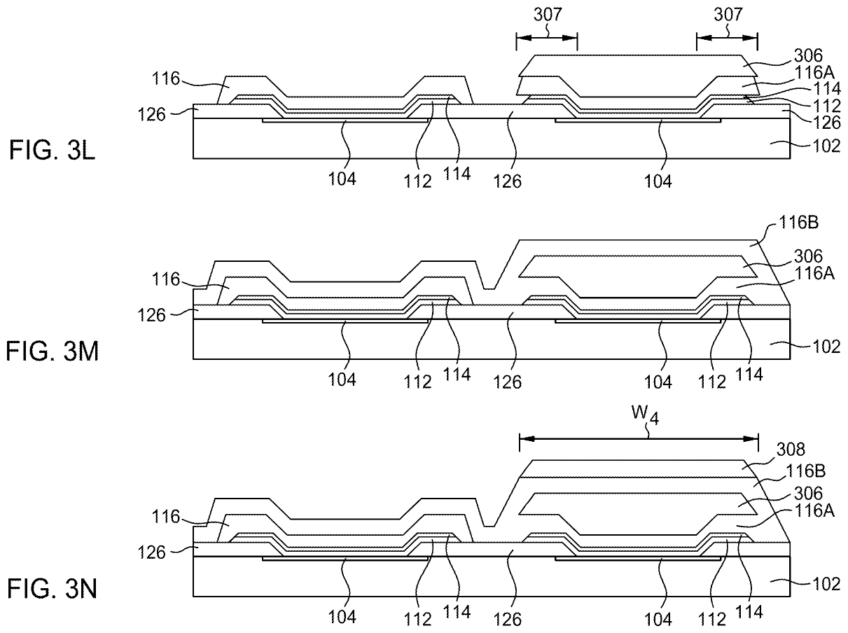

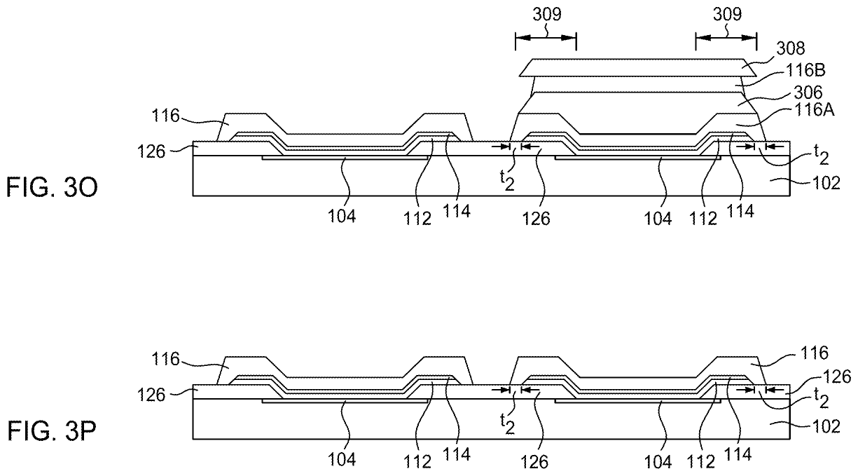

FIG. 2 is a flow diagram of a method 200 for forming a sub-pixel circuit 100 having a plugless arrangement 101A. FIGS. 3A-3P are schematic, cross-sectional views of substrate 102 during a method 200 for forming a sub-pixel circuit 100 having a plugless arrangement 101A.

At operation 201, as shown in FIG. 3A, the OLED material 112, the cathode 114, and a first encapsulation layer 116A of the first sub-pixel 108A are deposited over the substrate 102. The OLED material 112, the cathode 114, and a first encapsulation layer 116A are disposed over the PDL structures 126 and the metal-containing layer 104. In embodiments including capping layers, the capping layers are deposited between the cathode 114 and the first encapsulation layer 116A. The capping layers may be deposited by evaporation deposition. In one embodiment, the OLED material 112 and the cathode 114 are deposited using evaporation deposition.

At operation 202, as shown in FIG. 3B, a resist 302 is formed in a well of the first sub-pixel 108A. The resist 302 is disposed over the first encapsulation layer 116A. The resist 302 has a width W. The resist 302 is a positive resist or a negative resist. A positive resist includes portions of the resist which, when exposed to electromagnetic radiation, are respectively soluble to a resist developer applied to the resist after the pattern is written into the resist using the electromagnetic radiation. A negative resist includes portions of the resist which, when exposed to electromagnetic radiation, are respectively insoluble to a resist developer applied to the resist after the pattern is written into the resist using the electromagnetic radiation. The chemical composition of resist 302 determines whether the resist is a positive resist or a negative resist. The resist 302 is patterned to form one of a pixel opening 124A of the dot-type architecture 101C or a pixel opening 124B of the line-type architecture 101D of a first sub-pixel 108A. The patterning is one of a photolithography, digital lithography process, or laser ablation process.

At operation 203, as shown in FIG. 3C, the first encapsulation layer 116A exposed by the resist 302 is removed. The first encapsulation layer 116A exposed by resist 302 may be removed by dry etch process. At operation 204, as shown in FIG. 3D, the cathode 114 and the OLED material 112 exposed by the resist 302 are removed. The cathode 114 and the OLED material 112 exposed by resist 302 may be removed by dry etch process. The dry etch processes of operations 203 and 204 are anisotropic or substantially anisotropic. The width W₁ of resist 302 creates a buffer zone 303 over the PDL structure 126. Any residual isotropic etching that occurs during the dry etch processes is limited to the buffer zone 303. This results in limited damage to the OLED material 112 and cathode 114 of the first sub-pixel 108A.

At an operation 205, as shown in FIG. 3E, a second encapsulation layer 116B is deposited. The second encapsulation layer 116B is disposed over the resist 302 and the first encapsulation layer 116A. At optional operation 206, as shown in FIG. 3F, a resist 304 is formed over the second encapsulation layer in a well of the first sub-pixel 108A. In one embodiment, the resist 304 has a width W2 that is greater than the width W₁ of the resist 302. The resist 304 is a positive resist or a negative resist.

At optional operation 207, as shown in FIG. 3G, the second encapsulation layer 116B exposed by the resist 304 is removed. The second encapsulation layer 116B exposed by resist 304 may be removed by dry etch process. The dry etch process is anisotropic or substantially anisotropic. The width W2 of the resist 304 creates a buffer zone 305 over the PDL structure 126. Any residual isotropic etching that occurs during the dry etch process is limited to the buffer zone 305. This results in the second encapsulation layer 116B between the resist 302 and the resist 304 and a residual thickness t₁ adjacent to the first encapsulation layer 116A. The residual thickness t₁ of second encapsulation layer 116B isolates the cathode 114 and OLED material 112 from exposure to etchant in further etching operations. The first encapsulation layer 116A and the residual thickness t₁ of second encapsulation layer 116B result in the encapsulation layer 116 of FIG. 1A.

At operation 208, as shown in FIG. 3H, the resist 302, the optional resist 304, and the second encapsulation layer 116B between the resist 302 and the resist 304 are removed, forming the first sub-pixel 108A.

At operation 209, as shown in FIG. 3I, the OLED material 112, the cathode 114, and a first encapsulation layer 116A of the second sub-pixel 108B are deposited over the substrate 102. The OLED material 112, the cathode 114, and a first encapsulation layer 116A are disposed over the PDL structures 126 and the metal-containing layer 104. In embodiments including capping layers, the capping layers are deposited between the cathode 114 and the first encapsulation layer 116A. The capping layers may be deposited by evaporation deposition. In one embodiment, the OLED material 112 and the cathode 114 are deposited using evaporation deposition.

At operation 210, as shown in FIG. 3J, a resist 306 is formed in a well of the second sub-pixel 108B. The resist 306 is disposed over the first encapsulation layer 116A. The resist 306 has a width W₃. The resist 306 is a positive resist or a negative resist. The resist 306 is patterned to form one of a pixel opening 124A of the dot-type architecture 101C or a pixel opening 124B of the line-type architecture 101D of a second sub-pixel 108B. The patterning is one of a photolithography, digital lithography process, or laser ablation process.

At operation 211, as shown in FIG. 3K, the first encapsulation layer 116A exposed by the resist 306 is removed. The first encapsulation layer 116A exposed by resist 306 may be removed by dry etch process. At operation 212, as shown in FIG. 3L, the cathode 114 and the OLED material 112 exposed by the resist 306 are removed. The cathode 114 and the OLED material 112 exposed by resist 306 may be removed by dry etch process. The dry etch processes of operations 211 and 212 are anisotropic or substantially anisotropic. The width W₃ of resist 306 creates a buffer zone 307 over the PDL structure 126. Any residual isotropic etching that occurs during the dry etch processes is limited to the buffer zone 307. This results in limited damage to the OLED material 112 and cathode 114 of the second sub-pixel 108B.

At an operation 213, as shown in FIG. 3M, a second encapsulation layer 116B is deposited. The second encapsulation layer 116B is disposed over the resist 306 and the first encapsulation layer 116A. At optional operation 214, as shown in FIG. 3N, a resist 308 is formed over the second encapsulation layer in a well of the second sub-pixel 108B. In one embodiment, the resist 304 has a width W₄ that is greater than the width W₃ of the resist 306. The resist 308 is a positive resist or a negative resist.

At optional operation 215, as shown in FIG. 3O, the second encapsulation layer 116B exposed by the resist 308 is removed. The second encapsulation layer 116B exposed by resist 308 may be removed by dry etch process. The dry etch process is anisotropic or substantially anisotropic. The width W₄ of the resist 308 creates a buffer zone 309 over the PDL structure 126. Any residual isotropic etching that occurs during the dry etch process is limited to the buffer zone 309. This results in the second encapsulation layer 116B between the resist 306 and the resist 308 and a residual thickness t2 adjacent to the first encapsulation layer 116A. The residual thickness t2 of second encapsulation layer 116B isolates the cathode 114 and OLED material 112 from further etching operations. The first encapsulation layer 116A and the residual thickness t2 of second encapsulation layer 116B result in the encapsulation layer 116 of FIG. 1A.

At operation 216, as shown in FIG. 3P, the resist 306, the optional resist 308, and the second encapsulation layer 116B between the resist 306 and the resist 308 are removed, forming the second sub-pixel 108B.

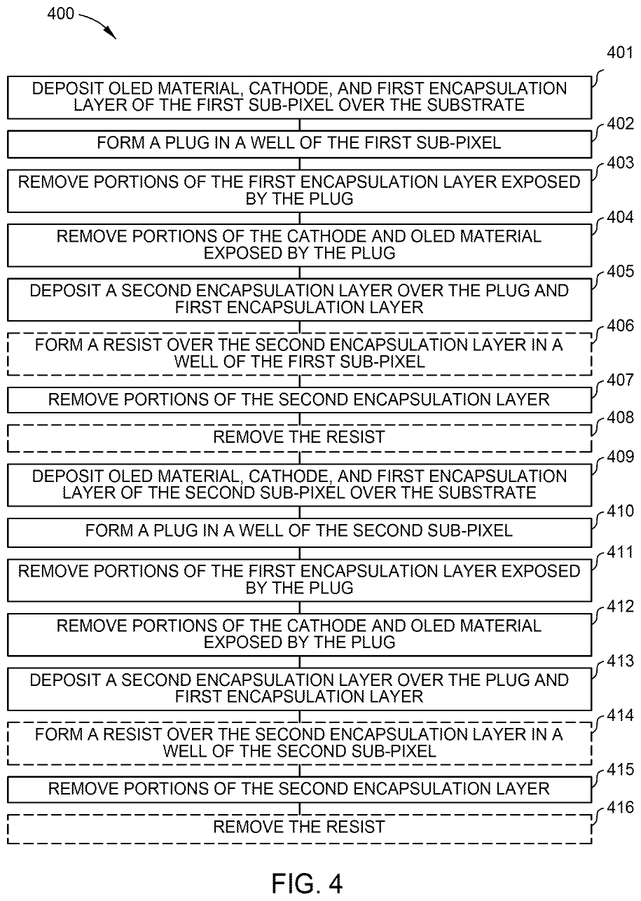

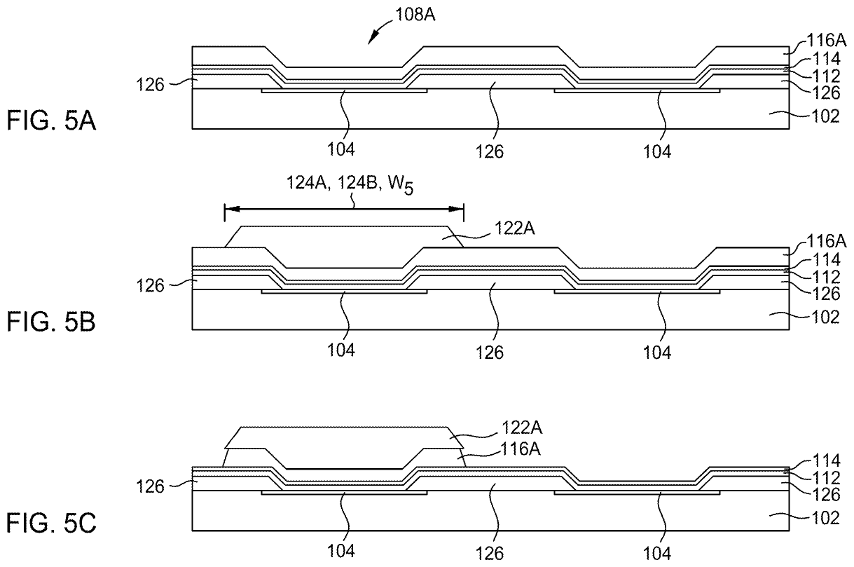

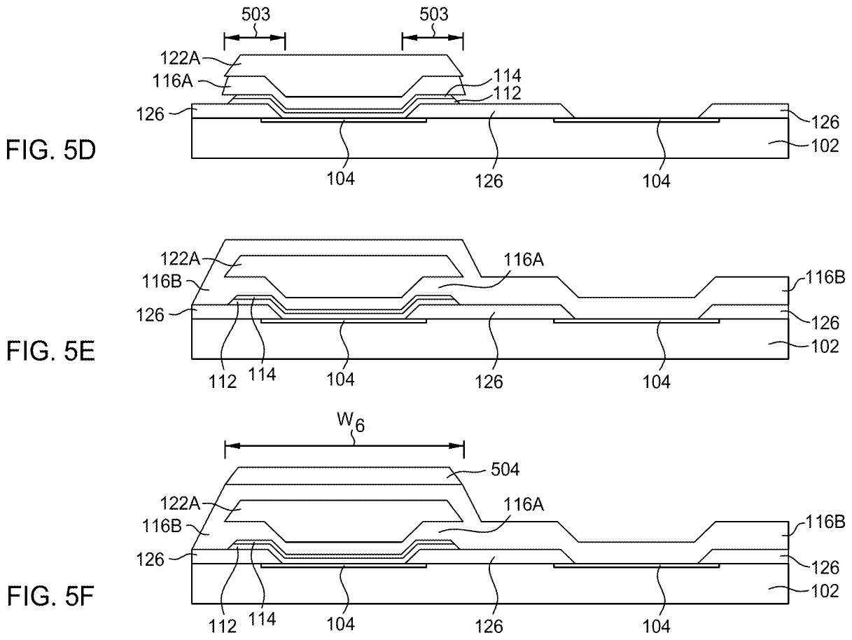

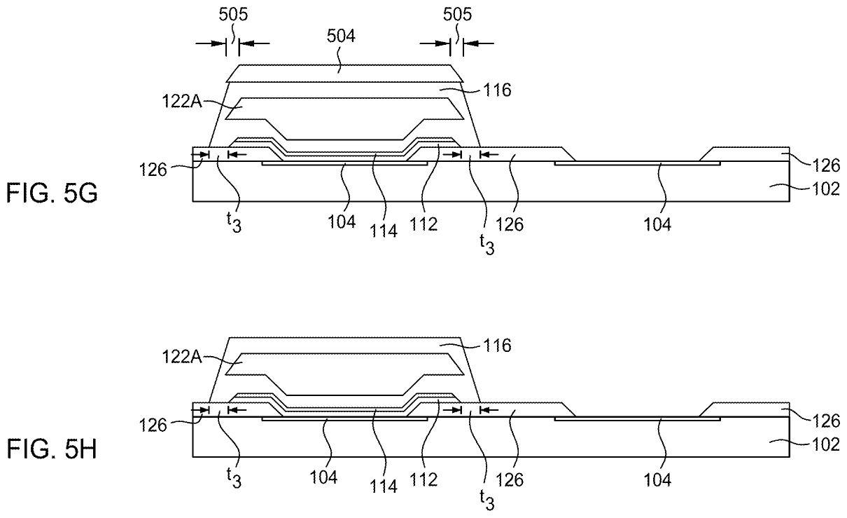

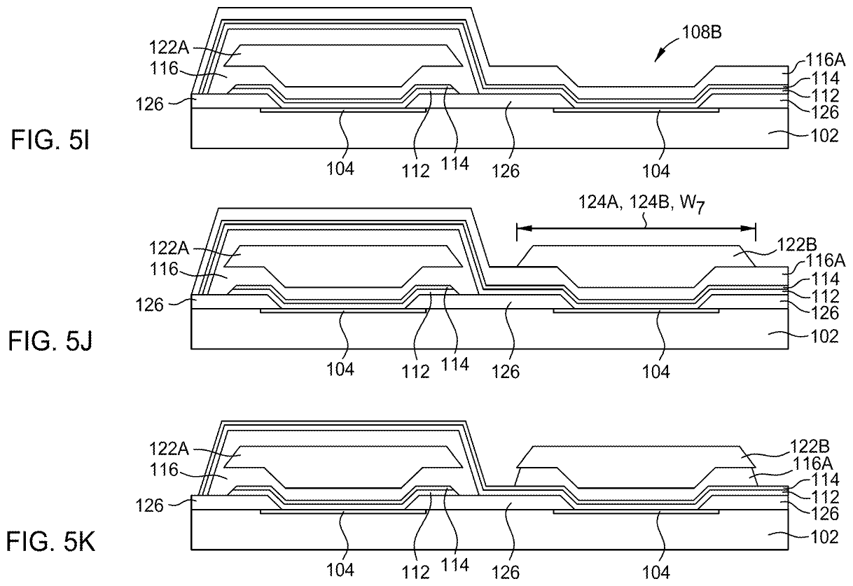

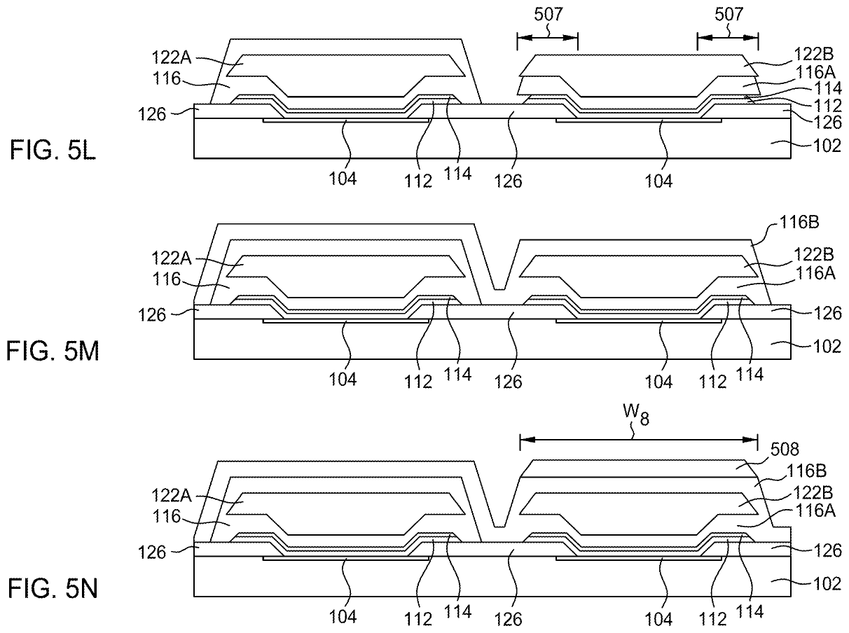

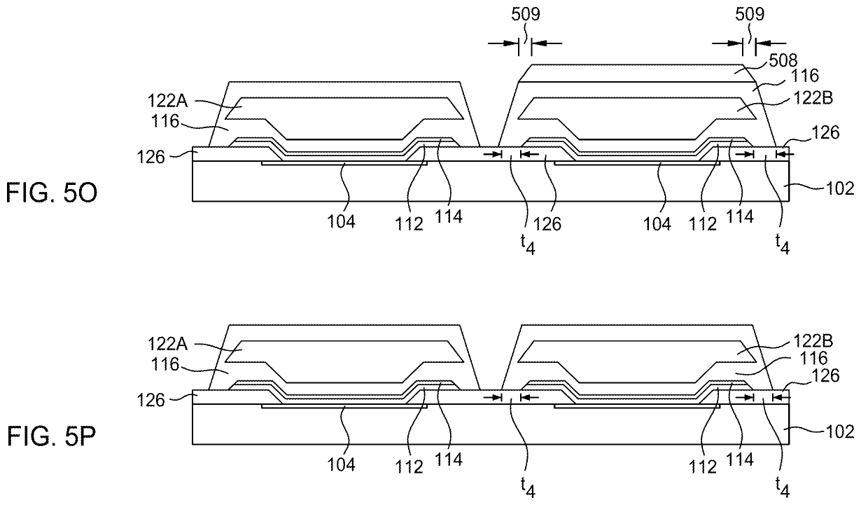

FIG. 4 is a flow diagram of a method 400 for forming a sub-pixel circuit 100 having a plug arrangement 101B. FIGS. 5A-5P are schematic, cross-sectional views of a substrate 102 during the method 400 for forming a sub-pixel circuit 100 having a plug arrangement 101B.

At operation 401, as shown in FIG. 5A, the OLED material 112, the cathode 114, and a first encapsulation layer 116A of the first sub-pixel 108A are deposited over the substrate 102. The OLED material 112, the cathode 114, and a first encapsulation layer 116A are disposed over the PDL structures 126 and the metal-containing layer 104. In embodiments including capping layers, the capping layers are deposited between the cathode 114 and the first encapsulation layer 116A. The capping layers may be deposited by evaporation deposition. In one embodiment, the OLED material 112 and the cathode 114 are deposited using evaporation deposition.

At operation 402, as shown in FIG. 5B, a plug 122A is formed in a well of the first sub-pixel 108A. The plug 122A is disposed over the first encapsulation layer 116A. The plug 122A has a width W₅. The plug 122A includes, but is not limited to, a photoresist, a color filter, or a photosensitive monomer. The plug 122A have a plug transmittance that is matched or substantially matched to an OLED transmittance of the OLED material 112. The plug 122A may each be the same material and match the OLED transmittance. The plug 122A may be different materials that match the OLED transmittance of each respective sub-pixel of the plurality of sub-pixels 106. The matched or substantially matched plug transmittance and OLED transmittance allow for the plug 122A to remain over the sub-pixels 106 without blocking the emitted light from the OLED material 112. The plug 122A is able to remain in place and thus do not require a lift off procedure to be removed from the sub-pixel circuit 100. The plug 122A is patterned to form one of a pixel opening 124A of the dot-type architecture 101C or a pixel opening 124B of the line-type architecture 101D of a first sub-pixel 108A.

At operation 403, as shown in FIG. 5C, the first encapsulation layer 116A exposed by the plug 122A is removed. The first encapsulation layer 116A exposed by plug 122A may be removed by dry etch process. At operation 404, as shown in FIG. 5D, the cathode 114 and the OLED material 112 exposed by the plug 122A are removed. The cathode 114 and the OLED material 112 exposed by plug 122A may be removed by dry etch process. The dry etch processes of operations 403 and 404 are anisotropic or substantially anisotropic. The width W₅ of plug 122A creates a buffer zone 503 over the PDL structure 126. Any residual isotropic etching that occurs during the dry etch processes is limited to the buffer zone 503. This results in limited damage to the OLED material 112 and cathode 114 of the first sub-pixel 108A.

At an operation 405, as shown in FIG. 5E, a second encapsulation layer 116B is deposited. The second encapsulation layer 116B is disposed over the plug 122A and the first encapsulation layer 116A. At optional operation 406, as shown in FIG. 5F, a resist 504 is formed in a well of the first sub-pixel 108A. In one embodiment, the resist 504 has a width W₆ that is greater than the width W₅ of the plug 122A. The resist 504 is a positive resist or a negative resist.

At operation 407, as shown in FIG. 5H, portions of the second encapsulation layer 116B are removed. In embodiments without a resist 504, the second encapsulation layer 116B disposed in the well of the first sub-pixel 108A is removed. In embodiments with the resist 504, as shown in FIG. 5G, the portions of the second encapsulation layer 116B exposed by the resist 504 is removed. The second encapsulation layer 116B may be removed by dry etch process. The dry etch process is anisotropic or substantially anisotropic. The width W₆ of the resist 504 creates a buffer zone 505 over the PDL structure 126. Any residual isotropic etching that occurs during the dry etch process is limited to the buffer zone 505. This results in the second encapsulation layer 116B between the plug 122A and the resist 504 and a residual thickness t3 of the first encapsulation layer 116A and second encapsulation layer 116B adjacent to the cathode 114 and OLED material 112. The first encapsulation layer 116A and the second encapsulation layer 116B result in the encapsulation layer 116 of FIG. 1B. The residual thickness t3 of encapsulation layer 116 isolates the cathode 114 and OLED material 112 from further etching operations. At optional operation 408, as shown in FIG. 5H, the resist 504 is removed, forming the first sub-pixel 108A.

At operation 409, as shown in FIG. 5I, the OLED material 112, the cathode 114, and a first encapsulation layer 116A of the second sub-pixel 108B are deposited over the substrate 102. The OLED material 112, the cathode 114, and a first encapsulation layer 116A are disposed over the PDL structures 126 and the metal-containing layer 104. In embodiments including capping layers, the capping layers are deposited between the cathode 114 and the first encapsulation layer 116A. The capping layers may be deposited by evaporation deposition. In one embodiment, the OLED material 112 and the cathode 114 are deposited using evaporation deposition.

At operation 410, as shown in FIG. 5J, a plug 122B is formed in a well of the second sub-pixel 108B. The plug 122B is disposed over the first encapsulation layer 116A. The plug 122B has a width W₇. The plug 122B includes, but is not limited to, a photoresist, a color filter, or a photosensitive monomer. The plug 122B have a plug transmittance that is matched or substantially matched to an OLED transmittance of the OLED material 112. The plug 122B may each be the same material and match the OLED transmittance. The plug 122B may be different materials that match the OLED transmittance of each respective sub-pixel of the plurality of sub-pixels 106. The matched or substantially matched plug transmittance and OLED transmittance allow for the plug 122B to remain over the sub-pixels 106 without blocking the emitted light from the OLED material 112. The plug 122B is able to remain in place and thus do not require a lift off procedure to be removed from the sub-pixel circuit 100. The plug 122B is patterned to form one of a pixel opening 124A of the dot-type architecture 101C or a pixel opening 124B of the line-type architecture 101D of a second sub-pixel 108B.

At operation 411, as shown in FIG. 5K, the first encapsulation layer 116A exposed by the plug 122B is removed. The first encapsulation layer 116A exposed by plug 122B may be removed by dry etch process. At operation 412, as shown in FIG. 5L, the cathode 114 and the OLED material 112 exposed by the plug 122B are removed. The cathode 114 and the OLED material 112 exposed by plug 122B may be removed by dry etch process. The dry etch processes of operations 411 and 412 are anisotropic or substantially anisotropic. The width W₇ of plug 122B creates a buffer zone 507 over the PDL structure 126. Any residual isotropic etching that occurs during the dry etch processes is limited to the buffer zone 507. This results in limited damage to the OLED material 112 and cathode 114 of the second sub-pixel 108B.

At an operation 413, as shown in FIG. 5M, a second encapsulation layer 116B is deposited. The second encapsulation layer 116B is disposed over the plug 122B and the first encapsulation layer 116A. At optional operation 414, as shown in FIG. 5N, a resist 508 is formed in a well of the second sub-pixel 108B. In one embodiment, the resist 508 has a width W₈ that is greater than the width W₇ of the plug 122B. The resist 508 is a positive resist or a negative resist.

At operation 415, as shown in FIG. 5P, portions of the second encapsulation layer are removed. In embodiments without a resist 508, the second encapsulation layer 116B disposed in the well of the second sub-pixel 108A is removed. In embodiments with the resist 508, as shown in FIG. 5G, the portions of the second encapsulation layer 116B exposed by the resist 508 is removed. The second encapsulation layer 116B may be removed by dry etch process. The dry etch process is anisotropic or substantially anisotropic. The width W₈ of the resist 508 creates a buffer zone 509 over the PDL structure 126. Any residual isotropic etching that occurs during the dry etch process is limited to the buffer zone 509. This results in the second encapsulation layer 116B between the plug 122B and the resist 508 and a residual thickness t₄ of the first encapsulation layer 116A and second encapsulation layer 116B adjacent to the cathode 114 and OLED material 112. The first encapsulation layer 116A and the second encapsulation layer 116B result in the encapsulation layer 116 of FIG. 1B. The residual thickness t₄ of the encapsulation layer 116 isolates the cathode 114 and OLED material 112 from further etching operations. At operation 416, as shown in FIG. 5P, the resist 508 is removed, forming the second sub-pixel 108B.

In summation, described herein are sub-pixel circuits and methods of forming sub-pixel circuits that may be utilized in a display such as an organic light-emitting diode (OLED) display. Adjacent PDL structures define each sub-pixel of the sub-pixel circuit using evaporation deposition. Evaporation deposition may be utilized for deposition of OLED materials, cathodes, and encapsulation layers. Resists may be deposited to control the ends of the OLED materials, ends of the cathodes, and the sidewalls of the encapsulation layer to insulate the OLED materials and cathodes from etchant in further etching operations. A plug may be used to augment the performance of the OLED display.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
a plurality of adjacent pixel-defining layer (PDL) structures disposed over the substrate, the PDL structure having a top surface coupled to adjacent sidewalls of the PDL structure;
a plurality of sub-pixels defined by the PDL structures, each sub-pixel comprising:
an anode;
an organic light emitting diode (OLED) material disposed over the anode, the OLED material having a first OLED end and a second OLED end that extend over the top surface of the PDL structure past the adjacent sidewalls;
a cathode disposed over the OLED material, the cathode having a first cathode end and a second cathode end that extend over the top surface of the PDL structure past the adjacent sidewalls; and
an encapsulation layer disposed over the cathode, wherein the encapsulation layer has a first sidewall and a second sidewall, wherein the first sidewall and the second sidewall extend past the first OLED end, the second OLED end, the first cathode end, and the second cathode end.

2. The device of claim 1, wherein the anode includes one or more layers comprising a transparent conductive oxide material, chromium, titanium, gold, silver, copper, aluminum, ITO, or a combination thereof.

3. The device of claim 1, wherein:
the first OLED end and the second OLED end extend over the top surface of the PDL structure past an endpoint of the anode; and
the first cathode end and the second cathode end extend over the top surface of the PDL structure past an endpoint of the anode.

4. The device of claim 1, wherein the plurality of sub-pixels includes a first sub-pixel and a second sub-pixel, wherein a gap separates the first sidewall of the encapsulation layer of the second sub-pixel from the second sidewall of the encapsulation layer of the first sub-pixel.

5. The device of claim 4, further comprising a global passivation layer disposed over the encapsulation layer, wherein the global passivation layer is disposed over the first sidewall and second sidewall of the encapsulation layer and a portion of the top surface of the PDL structures in the gap.

6. The device of claim 5, wherein the global passivation layer contacts the first sidewall and second sidewall of the encapsulation layer and the portion of the top surface of the PDL structures in the gap.

7. A method of forming a device, comprising:
positioning a substrate, the substrate comprising:
a first opening of a first sub-pixel defined by a plurality of adjacent pixel-defining layer (PDL) structures disposed over the substrate;
a first anode defined by the adjacent PDL structures;
depositing an OLED material, a cathode, and an encapsulation layer of the first sub-pixel over the substrate;
forming a resist in a well of the first sub-pixel;
removing the encapsulation layer of the first sub-pixel exposed by the resist of the first sub-pixel;
removing the OLED material and the cathode of the first sub-pixel exposed by the resist of the first sub-pixel;
positioning the substrate, the substrate further comprising:
a second opening of a second sub-pixel defined by the plurality of PDL structures disposed over the substrate;
a second anode defined by the adjacent PDL structures;
depositing an OLED material, a cathode, and an encapsulation layer of the second sub-pixel over the substrate;
forming a resist in a well of the second sub-pixel;
removing the encapsulation layer of the second sub-pixel exposed by the resist;
removing the OLED material and cathode of the second sub-pixel exposed by the resist; and
removing the resist of the second sub-pixel.

8. The method of claim 7, further comprising:
depositing a second encapsulation layer over the resist and the encapsulation layer of the first sub-pixel after removing the encapsulation layer, the OLED material and the cathode of the first sub-pixel exposed by the resist of the first sub-pixel;
and
removing portions of the second encapsulation layer.

9. The method of claim 8, further comprising:
forming a second resist over the second encapsulation layer in a well of the first sub-pixel; and
removing portions of the second encapsulation layer exposed by the second resist.

10. The method of claim 7, further comprising removing the resist from the first sub-pixel prior to positioning the substrate and depositing an OLED material, a cathode, and an encapsulation layer of the second sub-pixel over the substrate.

11. The method of claim 8, wherein the anode includes one or more layers comprising a transparent conductive oxide material, chromium, titanium, gold, silver, copper, aluminum, ITO, or a combination thereof.

12. The method of claim 8, wherein:
the PDL structure has a top surface coupled to adjacent sidewalls of the PDL structure;
the OLED material has a first OLED end and a second OLED end that extend over the top surface of the PDL structure past the adjacent sidewalls of the PDL structures; and
the cathode has a first cathode end and a second cathode end that extend over the top surface of the PDL structure past the adjacent sidewalls of the PDL structures.

13. The method of claim 8, further comprising a global passivation layer disposed over the encapsulation layer, wherein the global passivation layer contacts a first sidewall and a second sidewall of the encapsulation layer and a portion of a top surface of the PDL structures in a gap.

14. The method of claim 7, further comprising:
depositing a second encapsulation layer over the resist and the encapsulation layer of the second sub-pixel after removing the encapsulation layer, the OLED material and the cathode of the second sub-pixel exposed by the resist of the second sub-pixel;
and
removing portions of the second encapsulation layer of the second sub-pixel.

15. The method of claim 14, further comprising:
forming a second resist over the second encapsulation layer in a well of the first sub-pixel; and
removing portions of the second encapsulation layer exposed by the second resist.

16. The method of claim 14, further comprising removing the resist from the first sub-pixel prior to positioning the substrate and depositing an OLED material, a cathode, and an encapsulation layer of the second sub-pixel over the substrate.

17. The method of claim 14, wherein the anode includes a first transparent conductive oxide (TCO) layer, a metal-containing layer disposed over the first TCO layer, and a second TCO layer disposed over the metal-containing layer.

18. The method of claim 14, wherein:
the PDL structure has a top surface coupled to adjacent sidewalls of the PDL structure;
the OLED material has a first OLED end and a second OLED end that extend over the top surface of the PDL structure past the adjacent sidewalls of the PDL structures; and
the cathode has a first cathode end and a second cathode end that extend over the top surface of the PDL structure past the adjacent sidewalls of the PDL structures.

19. The method of claim 14, further comprising a global passivation layer disposed over the encapsulation layer, wherein the global passivation layer contacts a first sidewall and a second sidewall of the encapsulation layer and a portion of a top surface of the PDL structures in a gap.

20. A device, comprising:
a substrate;
a plurality of adjacent pixel-defining layer (PDL) structures disposed over the substrate, the PDL structure having a top surface coupled to adjacent sidewalls of the PDL structure;
a plurality of sub-pixels defined by the PDL structures, each sub-pixel comprising:
an anode;
an organic light emitting diode (OLED) material disposed over the anode, the OLED material having a first OLED end and a second OLED end that extend over the top surface of the PDL structure past the adjacent sidewalls;
a cathode disposed over the OLED material, the cathode having a first cathode end and a second cathode end that extend over the top surface of the PDL structure past the adjacent sidewalls;
a plug, the plug disposed over the cathode; and
an encapsulation layer disposed over the plug, wherein the encapsulation layer has a first sidewall, and a second sidewall, wherein the first sidewall and the second sidewall extend past the first OLED end, the second OLED end, the first cathode end, and the second cathode end.

21. The device of claim 20, wherein the anode includes one or more layers comprising a transparent conductive oxide material, chromium, titanium, gold, silver, copper, aluminum, ITO, or a combination thereof.

22. The device of claim 20, wherein:
the first OLED end and the second OLED end extend over the top surface of the PDL structure past an endpoint of the anode; and
the first cathode end and the second cathode end extend over the top surface of the PDL structure past an endpoint of the anode.

23. The device of claim 20, wherein the plurality of sub-pixels includes a first sub-pixel and a second sub-pixel, wherein a gap separates the first sidewall of the encapsulation layer of the second sub-pixel from the second sidewall of the encapsulation layer of the first sub-pixel.

24. The device of claim 20, further comprising a global passivation layer disposed over the encapsulation layer, wherein the global passivation layer is disposed over the first sidewall and second sidewall of the encapsulation layer and a portion of the top surface of the PDL structures in a gap.

25. The device of claim 20, further comprising a global passivation layer disposed over the encapsulation layer, wherein the global passivation layer contacts the first sidewall and second sidewall of the encapsulation layer and a portion of the top surface of the PDL structures in a gap G.

26. A method of forming a device, comprising:
positioning a substrate, the substrate comprising:
a first opening of a first sub-pixel defined by a plurality of adjacent pixel-defining layer (PDL) structures disposed over the substrate;
a first anode defined by the adjacent PDL structures;
depositing an OLED material, a cathode, and an encapsulation layer of the first sub-pixel over the substrate;
forming a plug in a well of the first sub-pixel, the plug having a first plug transmittance that is matched or substantially matched to an OLED transmittance of the OLED material of the first sub-pixel;
removing the encapsulation layer of the first sub-pixel exposed by the plug of the first sub-pixel;
removing the OLED material and the cathode of the first sub-pixel exposed by the plug of the first sub-pixel;
depositing a second encapsulation layer over the plug and first encapsulation layer of the first sub-pixel;
removing portions of the second encapsulation layer disposed over a second sub-pixel;
positioning the substrate, the substrate further comprising:
a second opening of the second sub-pixel defined by the plurality of PDL structures disposed over the substrate;
a second anode defined by the adjacent PDL structures;
depositing an OLED material, a cathode, and an encapsulation layer of the second sub-pixel over the substrate;
forming a plug in a well of the second sub-pixel, the plug having a first plug transmittance that is matched to an OLED transmittance of the OLED material of the first sub-pixel;
removing the first encapsulation layer of the second sub-pixel exposed by the plug of the second sub-pixel; and
removing the OLED material and cathode of the second sub-pixel exposed by the plug of the second sub-pixel;
depositing a second encapsulation layer over the plug and first encapsulation layer of the second sub-pixel; and
removing portions of the second encapsulation layer disposed over a first sub-pixel.

27. The method of claim 26, further comprising:
forming a resist over the second encapsulation layer in a well of the first sub-pixel;
removing portions of the second encapsulation layer exposed by the resist; and
removing the resist over the second encapsulation layer in a well of the first sub-pixel.

28. The method of claim 26, further comprising:
forming a second resist over the second encapsulation layer in a well of the second sub-pixel; and
removing portions of the second encapsulation layer exposed by the second resist and
removing the second resist over the second encapsulation layer in a well of the second sub-pixel.

29. The method of claim 26, wherein:
the PDL structures have a top surface coupled to adjacent sidewalls of the PDL structures;
the OLED material has a first OLED end and a second OLED end that extend over the top surface of the PDL structure past the adjacent sidewalls of the PDL structures; and
the cathode has a first cathode end and a second cathode end that extend over the top surface of the PDL structure past the adjacent sidewalls of the PDL structures.

30. The method of claim 29, further comprising a global passivation layer disposed over the encapsulation layer, wherein the global passivation layer contacts a first sidewall and a second sidewall of the encapsulation layer and a portion of a top surface of the PDL structures in a gap.
